(19) United States
(12) Patent Application Publication
(10) Pub. No.: US 2007/0283884 A1
(43) Pub. Date: Dec. 13, 2007

(54) Ring assembly for substrate processing chamber

(75) Inventors: Jennifer Tiller, Santa Clara, CA (US); Allen K. Lau, Cupertino, CA (US); Marc O'Donnell Schweitzer, San Jose, CA (US); Steven V. Sansoni, Livermore, CA (US); Keith A. Miller, Sunnyvale, CA (US); Christopher Boitnott, Ilalf Moon Bay, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/444,175

(22) Filed: May 30, 2006

(51) Int. Cl. C23C 16/00; C23F 1/00

(52) U.S. Cl. 118/715; 156/345.51

(57) ABSTRACT

A ring assembly is provided for a substrate support used in a substrate processing chamber, the substrate support comprising an annular ledge and an inner perimeter sidewall. In one version, the ring assembly comprises (i) an L-shaped isolator ring comprising a horizontal leg resting on the annular ledge of the support, and a vertical leg abutting the inner perimeter sidewall of the support, and (ii) a deposition ring comprising an annular band having an overlap ledge that overlaps the horizontal leg of the isolator ring. In another version, the deposition ring comprises a dielectric annular band that surrounds and overlaps the annular ledge of the support, and a bracket and fastener.

### BACKGROUND

Embodiments of the present invention relate to a ring assembly for a substrate support in a substrate process chamber.

In the processing of substrates, such as semiconductor wafers and displays, a substrate is placed in a process chamber and exposed to an energized gas to deposit or etch material on the substrate. A typical process chamber comprises process components that include an enclosure wall to enclose a process zone, a gas supply to provide a gas in the chamber, a gas energizer to energize the process gas to process the substrate, a substrate support, and a gas exhaust port. The process chambers can include, for example, sputtering or physical vapor deposition (PVD), chemical vapor deposition (CVD), and etching chambers. In a PVD chamber, a target is sputtered to cause sputtered target material to deposit on a substrate facing the target. In CVD chambers, a process gas is thermally or otherwise decomposed to deposit material on a substrate. In an etch chamber, the substrate is etched with a process gas having etching components.

The process chamber can also comprise a process kit, which typically includes components that assist in securing and protecting the substrate during processing, such as for example, annular structures located about the periphery of the substrate, for example, deposition rings, cover rings and shadow rings. For example, in PVD and CVD chambers, a ring assembly, which includes a deposition ring is often provided around the substrate to shield the sidewall and peripheral edge of the substrate support from the process deposits. The deposition ring is typically an annular metal ring with a ledge that rests on the substrate support and is provided to receive process deposits which would otherwise deposit on the exposed portions of the substrate support. The deposition ring increases the processing run time for the chamber as it can be periodically removed from the chamber and cleaned, for example, with HF and HNO₃, to remove accumulated deposits. The deposition ring can also reduce erosion of the support by the energized gas in the chamber.

However, in certain processes, the deposition ring is subject to elevated temperatures during processing which can result in warping of the ring as the ring is repeatedly heated and cooled during process cycles. Such warpage causes gaps to form between the ring and the support which allow the plasma to erode or form process deposits on the support. In some processes, such as tantalum PVD processes, the plasma heats up the deposition ring to undesirably high temperatures which further contribute to ring deformation. Also, excessive heating of rings is detrimental, because their expansion during heating cycles and subsequent contraction during cooling cycles, causes spalling of the process deposits formed on the deposition ring. Also, excessively hot rings can create high temperatures around the periphery of the substrate, which undesirably affect local processing temperatures on the substrate edge. The deposition rings can also erode during cleaning and refurbishment, especially when the cleaning process uses strong chemicals to clean the deposits adhered to the rings, such as tantalum deposits.

Accordingly, it is desirable to have process kit components, such as ring assemblies, that resist deformation and warping even after numerous process cycles. It is also desirable for such rings to have minimal temperature variation and temperature gradients in the chamber during substrate processing cycles. It is furthermore desirable to have a ring that does not excessively erode when cleaned by conventional cleaning processes.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a sectional side view of an embodiment of a ring assembly on an annular ledge of a substrate support;

FIG. 1A is a sectional side view of the isolator ring and a laser drill to form a laser textured surface on the isolator ring;

FIG. 1B is a detailed sectional side view of the recesses of the textured surface of the isolator ring;

FIG. 2 is a sectional view of another embodiment of a ring assembly on a substrate support; and

FIG. 3 is a partial sectional side view of an embodiment of process chamber having a ring assembly.

### DESCRIPTION

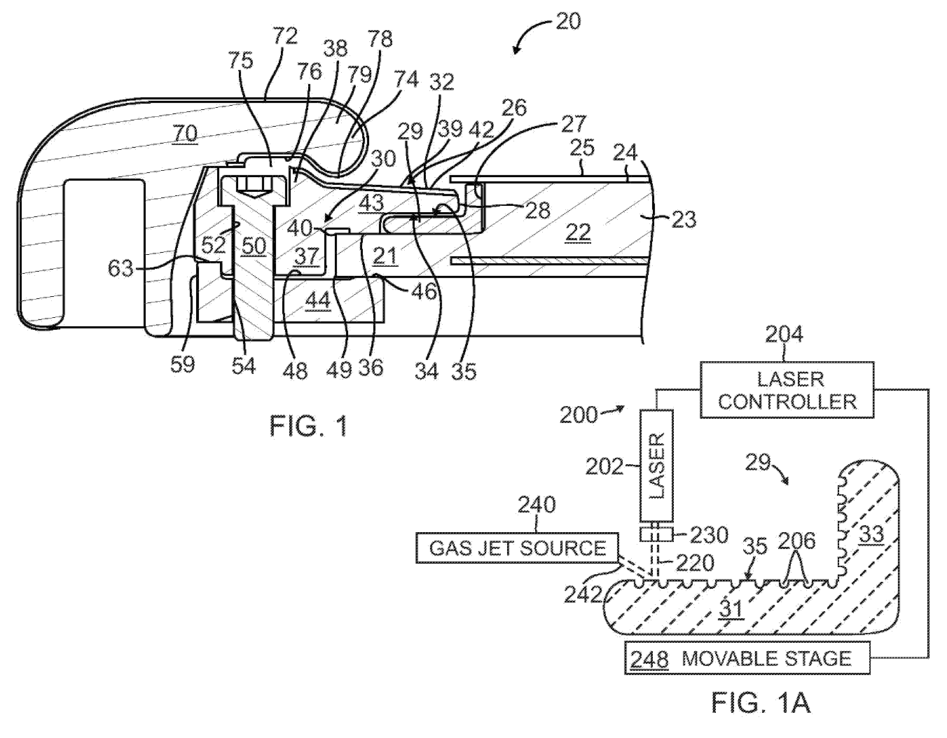

An exemplary version of a ring assembly 20 that can be used to cover or protect at least a portion of a substrate support 22 in a substrate-processing environment formed within a substrate processing chamber, is shown in FIG. 1. The substrate support 22 has a raised substrate-receiving surface 24 that receives and supports a substrate 25 during processing, the raised surface 24 having a perimeter sidewall 27, which lies below an overhanging edge of the substrate 25. The support 22 also has an annular ledge 21 that surrounds the circumference of the inner perimeter sidewall 27 of the raised surface 24. The substrate support 22 may comprise, for example, an electrostatic chuck 23 (as shown), a vacuum chuck, or a mechanical chuck.

The ring assembly 20 comprises a deposition ring 26 having an inner perimeter 28 that surrounds an L-shaped isolator ring 29. The deposition ring 26 and isolator ring 29 cooperate to protect the peripheral edge 30 of the support 22 to reduce its erosion in the process gas environment in the chamber and also to limit the accumulation of process deposits on the support 22.

The isolator ring 29 is L-shaped with a horizontal leg 31 joined to a vertical leg 33 with chamfered corners. The horizontal leg 31 rests on the annular ledge 21 of the support 22 and has a length that is sized smaller than the length of the annular ledge 21. For example, the length of the horizontal leg 31 can be sized to be less than about 80% of the length of the annular ledge 21 so that it stops short of the circumferential edge of the ledge 21. For example, when the length of the annular ledge 21 is from about 10 mm to about 15 mm, the length of the horizontal leg 31 is from about 6 mm to about 11 mm. The vertical leg 33 abuts the inner perimeter sidewall 27 of the support 22 and has a length that is sized smaller than the height of the inner perimeter sidewall 27, for example, a height of less than about 90% of the height of the inner perimeter sidewall 27. For example, when the height of the inner perimeter sidewall 27 is from about 5.5 mm to about 6.5 mm, the length of the vertical leg 33 is from about 5.2 mm to about 6.2 mm.

The isolator ring 29 is composed of a dielectric material, such as a ceramic, for example, aluminum oxide or silicon oxide. The isolator ring 29 of ceramic is more rigid than a corresponding metal structure, and advantageously, it retains its shape without warping from residual stresses even after numerous processing cycles. Also, the isolator ring 29 is made from a ceramic material that is selected to be resistant to erosion in the process environment of the chamber. As such, the isolator ring 29 does not need additional protective surface coatings to protect it from erosion in the plasma environment as with conventional ring assemblies. The protective coatings are often the cause of residual stresses in such structures, which result in warpage or deformation of the structures with exposure to plasma process cycles. A main source of stress in the metal rings is the residual stresses from machining. When the rings are heated in the chamber, the stresses are relieved and the component warps. For example, the isolator ring 29 is made from aluminum oxide when the processing environment comprises a plasma of argon.

The deposition ring 26 comprises an annular band 43 that surrounds and overlaps the isolator ring 29 and at least partially covers a peripheral edge 30 of the support 22, to protectively enclose the peripheral edge 30 of the support 22. The deposition ring 26 comprises an overlap ledge 32 that overlaps a portion of the horizontal leg 31, and stops short of the vertical leg 33, of the isolator ring 29. Thus, the overlap edge has a length smaller than the length of the horizontal leg 31 of the isolator ring 29, for example, at least 10% smaller. The bottom surface 34 and the inner perimeter 28 of the overlap ledge 32 of the deposition ring 26 conform to the upper surface 35 of the isolator ring 29 to form a complex maze therebetween that prevents the ingress of plasma and stray process deposits to the peripheral edge 30 of the support 22.

The deposition ring 26 further comprises a footing 36, which extends downwardly from the deposition ring 26 to rest on the annular ledge 21 of the support 22 to support the band 26. The footing 36 is shaped and sized to press against the substrate support 22 substantially without inducing cracks or fractures in the support 20. For example, as shown, the footing 36 can comprise a substantially vertical post that extends downwardly from the overlap ledge 32 of the deposition ring 26. The footing 36 exerts a compressive stress on the ledge 21 while minimizing horizontally directed stresses to reduce the possibility of fracturing of the ledge 21. The cut-out or recessed sections around both sides of the footing 36 reduce the possibility of the footing 36 contacting or pressing against the outer corner 40 of the ledge 21 to cause it to crack or chip. The deposition ring 26 further comprises a lower sidewall 37, which extends downwardly over the peripheral edge 30 of the support 22.

The annular band 43 of the deposition ring 26 also has an upper wedge 38, which extends vertically upward and connects to the inner perimeter 28 to define a gently sloped surface 39 that serves to collect process deposits in a process cycle. The sloped surface 39 is typically at an angle of at least about 5° and can be even be up to about 25°. The gentle sloped surface allows process deposits to accumulate on the smooth uninterrupted sloped surface 39 to higher thickness levels than, for example, the thickness levels that can be accumulated on surfaces having sharp corners or edges, which typically cause the deposits to fracture and spall off due to more concentrated or variable thermal stress effects. In contrast to prior art deposition rings which sometimes have a bump adjacent depressions on which the process deposits accumulate, the sloped surface 39 of the deposition ring 26 is substantially absent such bumps or other protrusions. It was determined that the smooth uninterrupted sloped surface, advantageously, allows a higher thickness of process deposits to accumulate thereon, than on a bump because the variable thickness of the bump results in nonuniform thermal expansion stresses, which results in flaking and spalling of the deposits. The bump was found especially undesirable for the deposition of tantalum films because the thick compressive strained tantalum deposits was found to readily peel off such bump portions. The annular band 43 can also have an upper surface which is flat and not sloped.

The deposition ring 26 is preferably fabricated from metal because the complex geometry of the deposition ring 26 is easier to make from a metal than a ceramic. Because the inside portion of the ring assembly 20 comprises a separate structure formed by the isolator ring 29, the resultant smaller radial length of the deposition ring 26 reduces the amount of deformation and warpage that results from conventional deposition rings, which comprise a single piece of metal. Also, the isolator ring 29 being made from a ceramic can withstand the heat. The deposition ring 26 protects the covered surfaces of the support 22 from erosion by energized process gases and reduces the accumulation of process deposits on these surfaces. Suitable metals include for example, aluminum, stainless steel and titanium, of which stainless steel is typically used.

In one version, the sloped surface 39 of the deposition ring 26 comprises a textured coating 42 that is designed to have texture features to which the process deposits readily adhere to, and thus can accumulate to higher thickness. The textured coating 42 comprises features 52 that are shaped and sized to physically adhere process deposits by an interlocking mechanism. A suitable textured coating is a LAVACOAT™ coating from Applied Materials, as described in for example, U.S. patent application Ser. No. 10,880,235 to Tsai et al, assigned to Applied Materials, Inc, and filed on Jun. 28, 2004, which is herein incorporated by reference in its entirety. Optionally, the exposed surface of the isolator ring 29 can also be coated with such a coating.

The ring assembly 20 further comprises a bracket 44, which is also designed to reduce the amount of pressure or stress exerted on the annular ledge 21 of the support 22. For example, the bracket 44 may comprise a raised lip 46 that presses against the annular ledge 21 with substantially only a compressive force, and an adjacent recess 48, which provides a gap with the bottom corner 49 of the ledge 21 to limit the application of any thermal stress induced pressure on the bottom corner 49. The bracket 44 and the footing 36 of the deposition ring 26 may also be complementarily positioned such that the clamping force exerted by any one of these components against the annular ledge 21 is at least partially counteracted by the other. For example, the bracket 44 may press against the annular ledge 21 substantially directly below where the footing 36 presses, so the force on the ledge 21 is substantially equal above and below the ledge 21. This ring assembly 20 reduces cracking or fracturing of the substrate support 22 by exerting substantially only a vertical, compressive stress on the annular ledge 21 of the support 22, and substantially without pressing against portions of the support 22 that are readily cracked or chipped, such as corners, 40, 49 of the annular ledge 21.

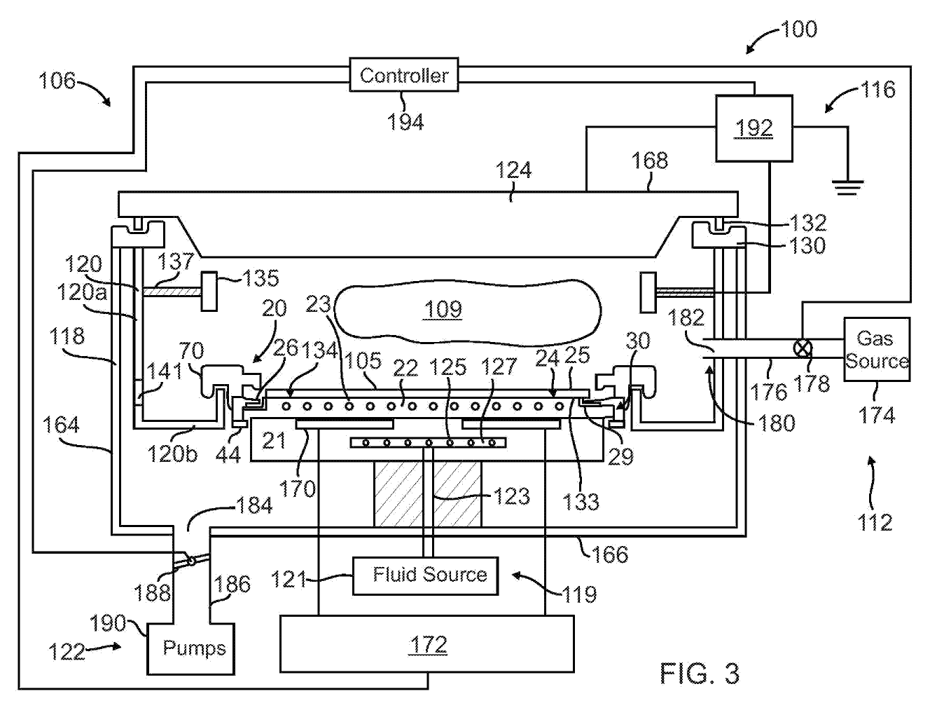

In one version, the ring assembly 20 can also include a fastener 50 that clamps the deposition ring 26 to the substrate support 22. Fastening of the deposition ring 26 to the support 22 provides improved processing results at least in part because better heat exchange can occur between the clamped deposition ring 26 and the support 22. Without such fastening, the deposition ring 26 is becomes excessively hot during substrate processing because, for example, the sloped surface 39 of the deposition ring 26 is exposed to the energetic impingement of plasma species from the surrounding plasma. As explained, excessive heating of the deposition ring 26 can lead to a thermal expansion stresses between the deposition ring 26 and overlying process deposits causing the process deposits to flake away from the sloped surface 39 and potentially contaminate the substrate 25. Fastening of the deposition ring 26 to the support 22 allows better heat exchange between the band 26 and the support 22 to reduce the temperature of the deposition ring 26. In addition, the support 22 can also be temperature controlled, for example, by providing a temperature controlled cooling plate 127 comprising cooling conduits 123 in the support 22, as shown for example shown in FIG. 3. Clamping of the deposition ring 26 to the support 22 also provides more secure coverage and protection of the support 22.

The fastener 50 extends through an opening 52 that extends from the sloped surface 39 of the deposition ring 26 to the bottom surface of the band. The fastener 50 comprises a fastener 50 that is shaped and sized to pass through the opening 52 of the deposition ring 26 and further through an opening 52 the bracket 44 to clamp the deposition ring 26 to the support 22. The fastener 50 can be for example a screw, clip, spring or nut. For example, in one version, the fastener 50 comprises a threaded screw that fits through the opening 52 in the deposition ring 26 and at least partially through an opening 52 in the bracket 44, which has a complimentary thread that allows the bracket 44 to be tightened against the support 22 upon turning the fastener 50. Also, a desired number of openings 52 and fasteners 50 can be provided to secure the deposition ring 26 to the support 22, for example, the ring assembly 20 can comprise from about 3 to about 24 of the openings 52, such as about 8 openings, that are placed in a desired configuration about the deposition ring 26.

In one version, the fastener 50 comprises a swivel nut that allows the bracket 44 to be rotated into place against the support 22 to rotate the bracket 44 into a desired position to clamp the deposition ring 26 against the support 22. The swiveling fastener 50 allows ready removal of the ring assembly 20, for example for cleaning of the assembly, substantially without requiring removal of the fastener from the bracket 44, and even substantially without requiring access to a portion of the ring assembly 20 or other element below the annular ledge 21 of the support 22.

Also, the bracket 44 may comprise additional features that enable the bracket to “lock” on to the deposition ring 26 to better secure the band 26. For example, the bracket 44 can comprise a raised wall 59 that is adapted to press against a peripheral recess 63 in the lower sidewall 37 of the deposition ring 26, to lock the deposition ring into a desired clamped position.

The ring assembly 20 can also include a cover ring 70 comprising a radially inwardly extending mantle 72 that extends across at least a portion of the deposition ring 26 to cover and protect portions of the band 26. In one version, the mantle 72 comprises a downwardly extending bump 74 that is sized and shaped to inhibit the deposition of process deposits on at least a portion of the sloped surface 39 of the deposition ring 26, for example, to inhibit the flow of plasma species and process deposits over the surface 39. The bump 74 comprises an apex 78 at an inner diameter 79 that extends downwardly toward the edge 38 of the sloped surface 39 of the deposition ring 26 to form a convoluted and constricted flow path 75 that inhibits the flow of process deposits past the bump 74. The apex 78 can extend height of about 2 mm to about 5 mm from a bottom surface 76 of the cover ring 70. The cover ring 70 is preferably fabricated of an erosion resistant material, which may be a metallic material such as for example at least one of stainless steel and titanium. The cover ring 70 may also be fabricated of a ceramic material, such as for example aluminum oxide. The cover ring 70 may also comprise a textured top surface to which process deposits may adhere.

In one version, the upper surface 35 of the isolator ring 29 comprises a laser textured surface, as shown in FIG. 1A. The laser texture is obtained using a laser beam drill 200 comprising a laser 202 and a laser controller 204. The laser beam drill 200 is used to laser drill a pattern of recesses 206 into the surface 35. Referring to the detail shown in FIG. 1B, the recesses 206 are formed as wells having a circular opening 208, sidewalls 210 and a curved bottom wall 212. The laser drilled recesses 206 improve adhesion of the process deposits formed in the plasma process by serving as openings within which the process deposits collect and remain adhered to the isolator ring 29. The textured surface 35 firmly adheres the process deposits substantially preventing flaking-off of the process deposits from the ring 29 by providing a mechanical locking force between the process deposits and the textured surface 35. In one version, the recesses 206 have an opening 208 with a diameter (a) of from about 25 to about 800 microns (1 to 30 mils), or even from 50 to 100 microns (2 to 4 mils). The recesses 206 can further have a depth (d) of from about 25 to about 800 microns (1 to 30 mils), or even from 50 to 400 microns (2 to 15 mils). The recesses 206 can also have a spacing (s) between center-points of adjacent recesses 206 of from about 25 to about 1000 microns (1 to 40 mils), or even from 25 to 200 microns (2 to 8 mils), or even about 125 mils (5 mils).

To form the recesses 206, the laser beam drill 200 directs a laser beam 220 onto the surface 35 of the isolator ring 29 to vaporize the material of the surface to create a deep recess 206. In one embodiment, the laser beam drill 200 comprises a laser 202 and laser controller 204 that generates a pulsed laser beam 220 having an intensity that modulates over time. The pulsed laser beam 220 uses a peak pulse power to improve vaporization of the surface material while minimizing heat loss to provide better control over the shape of the recess 206. The laser energy successively dissociates layers of molecules of the surface 35 without excessive heat transfer to the material. The laser 202 preferably comprises, for example, an excimer laser that generates an ultra-violet laser beam having a wavelength of less than about 360 nanometer, for example, about 355 nanometer. A suitable excimer laser is commercially available, for example, from Resonetics, Inc., Nashua, N.H.

The laser beam drill 200 can also include an optical system 230 that can include an auto-focusing mechanism that determines the distance between the laser 202 and the surface 35 of the ring 29, and focuses the laser beam 220 accordingly. For example, the auto-focusing mechanism may reflect a light beam from the surface 35 and detect the reflected light beam to determine the distance to the surface. The detected light beam can be analyzed, for example, by an interferometric method. The laser beam drill 200 may further comprise a gas jet source 240 to direct a gas stream 242 towards the surface region being laser drilled. The gas stream removes vaporized material from the region to improve the speed and uniformity of drilling and to prevent or reduce deposition of vaporized material on the optical system 230. The gas may comprise, for example, an inert gas. The gas jet source 240 comprises a nozzle at some standoff distance from the ring 29 to focus and direct the gas in a stream onto the surface 35. The ring 29 to be laser drilled is typically mounted on a moveable stage 248 to allow the laser beam 220 to be positioned at different points on the surface 35 of the isolator ring 29 to drill the recesses 206. For example, a suitable stage 248 can be a 4-5 axis motion system capable of ±1 micron incremental motion in the X, Y, Z directions with a resolution of ±0.5 microns and a maximum velocity of 50 mm/seconds. The laser controller 204 also operates the movable stage 248.

The recesses 206 are laser drilled by directing the pulsed laser beam 220 towards a position on the surface 35 of the isolator ring 29 to vaporize a portion of the structure. The pulsed laser beam 220 is then directed onto another position on the surface 35 of the ring 29 to vaporize another portion of the surface to form another recess 206. These steps are repeated to create a pattern of recesses 206 in the surface 35 of the isolator ring 29. The laser beam drill 200 is controlled by the laser controller 204 which can set the peak pulse power, pulse duration, and pulsing frequency, of the laser beam 220. The pulsed laser beam 220 is operated at a peak power level sufficiently high to remove the desired depth of material. For example, to form a textured surface 35, the pulsed laser beam 220 can be operated at a preselected power level sufficiently high to form a recess 206 having a curved bottom wall 212 that terminates in the isolator ring 29 without drilling through the entire thickness of the ring. The laser beam 220 is focused at a point on the surface 35 where a recess 29 is to be formed to transform the material at the point by heating the material to a sufficiently high temperature to liquid and/or vapor phases. The desired recess structure is formed, pulse-by-pulse by removal of liquid and vapor phases from the site. For example, a laser 202 comprising an UV pulsed excimer laser can be operated at a pulse width (time of each pulse) of from about 10 to about 30 nanoseconds, an average power level of from about 10 to about 400 Watts, and a pulsing frequency of from about 100 Hz to about 10,000 Hz. During the 10 to 30 nanosecond pulsed laser operation, the transformation of material from the solid phase to the liquid and vapor phase is sufficiently rapid that there is virtually no time for heat to be transferred into the body of the ring 29 which may otherwise cause local micro-cracking of the structure.

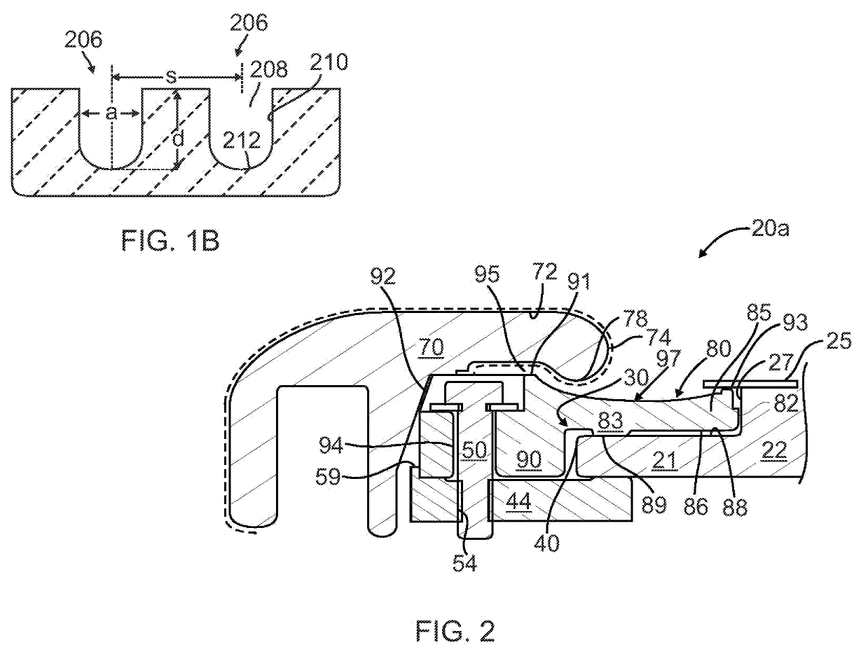

Another version of a ring assembly 20a around the support 22 comprises a unitary deposition ring 80 that rests on the annular ledge 21 of the support 22 as shown in FIG. 2. The deposition ring 80 has an inner perimeter 82 that directly abuts the inner perimeter sidewall 27 of the support 22 below the substrate 25. The deposition ring 80 is made from a dielectric material, such as a ceramic material, for example, aluminum oxide, silicon oxide or aluminum nitride. Because the deposition ring 80 is made from a ceramic material, this version does not have a separate isolator ring. Instead the ceramic deposition ring 80 comprises a unitary structure that is shaped protect the peripheral edge 30 of the support 22 to reduce its erosion in the process gas environment in the chamber and also to limit the accumulation of process deposits on the support 22. A deposition ring 80 made of a rigid ceramic is preferred because it retains its shape without warping from residual stresses even after numerous processing cycles. Also, the ceramic material is selected to be resistant to erosion in the process environment of the chamber. The deposition ring 80 can also be coated with an arc sprayed coating of aluminum. The aluminum arc sprayed coating is applied to the deposition ring 80 to improve the adhesion of process deposits onto the ring during operation.

The deposition ring 80 comprises an annular band 83 that surrounds and overlaps the annular ledge 21 to protectively enclose the peripheral edge 30 of the support 20. The annular band 83 comprises an overlap ledge 85 that overlaps the annular ledge 21 and stops short of the inner perimeter sidewall 27 of the support 22. Typically, the overlap edge has a length of less than about 90% of the length of the annular ledge. The bottom surface 86 and the inner perimeter 82 of the overlap ledge 85 conform to the upper surface 88 of the annular ledge 21 to form a complex maze therebetween that prevents the plasma from reaching the peripheral edge 30 of the support 22. The deposition ring 80 further comprises a footing 89 such as a substantially vertical post extending downwardly from the annular band 83 to rest on the annular ledge 21 of the support 22 to support the band 26. The cutout sections around both sides of the footing 89 reduces the possibility of the footing pressing against the outer corner 40 of the annular ledge 21. The deposition ring 80 further comprises a lower sidewall 90, which extends downwardly over the peripheral edge 30 of the support 22.

In this version, the deposition ring 80 has an outer rim 91 at its radially outer perimeter 92, which extends vertically upward from the annular band 83, and an inner rim 93, which also extends upward from the inner perimeter 82 of the annular band 83. The outer and inner rims 91, 93 are connected by a concave surface 93, which serves to collect process deposits in a process cycle. The concave surface 93 is curved at a radius of at least about 50°, or even from about 30° to about 80°. The concave surface 93 provides a depression that allows process deposits to accumulate to higher thickness level before the deposition ring 80 has to be removed for cleaning. The concave surface 93 is gently curved to reduce stresses on the accumulated deposits that occur on surfaces having sharp corners or edges. As with the previous version, the concave surface 93 of the deposition ring 80 is also substantially absent bumps or other protrusions which result in non-uniform thermal stresses that cause flaking or spalling of overlying deposits.

As before, the ring assembly 20a also comprises a bracket 44, which is also designed to reduce the amount of pressure or stress exerted on the annular ledge 21 of the support 22. The bracket 44 and the footing 89 of the deposition ring 80 are arranged in complementary positions that at least partially counteract the clamping force exerted by these components against the annular ledge 21 of the support 22.

The ring assembly 20a also includes a fastener 50 that clamps the deposition ring 80 to the substrate support 22. Fastening of the deposition ring 80 to the support 22 provides improved processing results at least in part because better heat exchange can occur between the dielectric material of the deposition ring 80 (which is typically a poor heat conductor as compared to a metal material) and the support 22. Without such fastening, the dielectric deposition ring 80 becomes too hot during processing leading to thermal expansion stresses between the deposition ring 80 and overlying process deposits. Fastening of the deposition ring 80 to the support 22 also provides more secure coverage and protection of the support 22. The fastener 50 extends through an opening 94 that extends from the outer rim 91 of the deposition ring 80. The fastener 50 can be, for example, a threaded screw that fits through the opening 94 in the deposition ring 80 and at least partially through an opening 52 in the bracket 44, which has a complimentary thread that allows the bracket 44 to be tightened against the support 22 upon turning the fastener 50. The bracket 44 comprises and he went in a raised wall 59 that is adapted to press against a peripheral recess 63 in the lower sidewall 37 may comprise additional features that enable the bracket to “lock” on to the deposition ring 80 to better secure the band 26.

The ring assembly 20a can also include a cover ring 70 comprising a radially inwardly extending mantle 72 that extends across at least a portion of the deposition ring 80. The cover ring 70 comprises a downwardly extending bump 74 that has an apex 78 at an inner diameter 79 that extends downwardly toward the outer rim 91 of the deposition ring 80 to form a convoluted and constricted flow path 95 that inhibits the flow of plasma and process deposit formation past the bump 74.

An example of a suitable substrate processing apparatus 100 comprising a process chamber 106 having a ring assembly 20 with a deposition ring 26 and isolator ring 29, about a support 22, is shown in FIG. 3. The chamber 106 can also have the ring assembly 20a with the deposition ring 80 (not shown). The chamber 106 can be a part of a multi-chamber platform (not shown) having a cluster of interconnected chambers connected by a robot arm mechanism that transfers substrates 25 between different chambers. In the version shown, the process chamber 106 comprises a sputter deposition chamber, also called a physical vapor deposition or PVD chamber, which is capable of sputter depositing material on a substrate 25, such as one or more of tantalum, tantalum nitride, titanium, titanium nitride, copper, tungsten, tungsten nitride and aluminum. The chamber 106 comprises enclosure walls 118 that enclose a process zone 109, and that include sidewalls 164, a bottom wall 166, and a ceiling 168. A support ring 130 can be arranged between the sidewalls 164 and ceiling 168 to support the ceiling 168. Other chamber walls can include one or more shields 120 that shield the enclosure walls 118 from the sputtering environment.

The chamber 106 comprises the support 22 to support a substrate 25. The substrate support 22 may be electrically floating or can have an electrode 170 that is biased by a power supply 172, such as an RF power supply. The substrate support 22 can also comprise a moveable shutter disk 133 that can protect the upper surface 134 of the support 22 when the substrate 25 is not present. In operation, the substrate 25 is introduced into the chamber 106 through a substrate-loading inlet (not shown) in a sidewall 164 of the chamber 106 and placed on the support 22. The support 22 can be lifted or lowered by support lift bellows and a lift finger assembly (not shown) can be used to lift and lower the substrate onto the support 22 during transport of the substrate 25 into and out of the chamber 106.

The chamber 106 can further comprise a temperature control system 119 to control one or more temperatures in the chamber 106, such as a temperature of the support 22. In one version, the temperature control system 119 comprises a fluid supply adapted to provide heat exchange fluid to the support 22 from a fluid source 121. One or more conduits 123 deliver the heat exchange fluid from the fluid source 121 to the support 22. The support 22 can comprise one or more channels 125 therein, such as for example channels 125 in a metal cooling plate 127, through which the heat exchange fluid is flowed to exchange heat with the support 22 and control the temperature of the support 22. A suitable heat exchange fluid may be, for example, water. Controlling the temperature of the support 22 can also provide good temperature of elements that are in good thermal contact with the support 22, such as for example a substrate 25 on the surface 134 of the support 22, and also a clamped portion of a ring assembly 20.

The support 22 may also comprise the ring assembly 20 comprising one or more rings, such as the cover ring 70 and the deposition ring 26, which may be called a deposition ring, and which cover at least a portion of the upper surface 134 of the support 22, and such as a portion of the peripheral edge 30 of the support 22, to inhibit erosion of the support 22. The deposition ring 26 at least partially surrounds the substrate 25 to protect portions of the support 22 not covered by the substrate 25. The cover ring 70 encircles and covers at least a portion of the deposition ring 26, and reduces the deposition of particles onto both the deposition ring 26 and the underlying support 22. The ring assembly 20 further comprises a fastener 50 to clamp the deposition ring 26 onto the substrate support 22.

A process gas, such as a sputtering gas, is introduced into the chamber 106 through a gas delivery system 112 that includes a process gas supply comprising one or more gas sources 174 that each feed a conduit 176 having a gas flow control valve 178, such as a mass flow controller, to pass a set flow rate of the gas therethrough. The conduits 176 can feed the gases to a mixing manifold (not shown) in which the gases are mixed to from a desired process gas composition. The mixing manifold feeds a gas distributor 180 having one or more gas outlets 182 in the chamber 106. The process gas may comprise a non-reactive gas, such as argon or xenon, which is capable of energetically impinging upon and sputtering material from a target. The process gas may also comprise a reactive gas, such as one or more of an oxygen-containing gas and a nitrogen-containing gas, that are capable of reacting with the sputtered material to form a layer on the substrate 25. Spent process gas and byproducts are exhausted from the chamber 106 through an exhaust 122, which includes one or more exhaust ports 184 that receive spent process gas and pass the spent gas to an exhaust conduit 186 in which there is a throttle valve 188 to control the pressure of the gas in the chamber 106. The exhaust conduit 186 feeds one or more exhaust pumps 190. Typically, the pressure of the sputtering gas in the chamber 106 is set to sub-atmospheric levels.

The sputtering chamber 106 further comprises a sputtering target 124 facing a surface 105 of the substrate 25, and comprising material to be sputtered onto the substrate 25, such as for example at least one of tantalum and tantalum nitride. The target 124 is electrically isolated from the chamber 106 by an annular insulator ring 132, and is connected to a power supply 192. The sputtering chamber 106 also has a shield 120 to protect a wall 118 of the chamber 106 from sputtered material. The shield 120 can comprise a wall-like cylindrical shape having upper and lower shield sections 120a, 120b that shield the upper and lower regions of the chamber 106. In the version shown in FIG. 3, the shield 120 has an upper section 120a mounted to the support ring 130 and a lower section 120b that is fitted to the cover ring 70. A clamp shield 141 comprising a clamping ring can also be provided to clamp the upper and lower shield sections 120a,b together. Alternative shield configurations, such as inner and outer shields, can also be provided. In one version, one or more of the power supply 192, target 124, and shield 120, operate as a gas energizer 116 that is capable of energizing the sputtering gas to sputter material from the target 124. The power supply 192 applies a bias voltage to the target 124 with respect to the shield 120. The electric field generated in the chamber 106 from the applied voltage energizes the sputtering gas to form a plasma that energetically impinges upon and bombards the target 124 to sputter material off the target 124 and onto the substrate 25. The support 22 having the electrode 170 and power supply 172 may also operate as part of the gas energizer 116 by energizing and accelerating ionized material sputtered from the target 124 towards the substrate 25. Furthermore, a gas-energizing coil 135 can be provided that is powered by a power supply 192 and that is positioned within the chamber 106 to provide enhanced energized gas characteristics, such as improved energized gas density. The gas-energizing coil 135 can be supported by a coil support 137 that is attached to a shield 120 or other wall in the chamber 106.

The chamber 106 can be controlled by a controller 194 that comprises program code having instruction sets to operate components of the chamber 106 to process substrates 25 in the chamber 106. For example, the controller 194 can comprise a substrate positioning instruction set to operate one or more of the substrate support 22 and substrate transport to position a substrate 25 in the chamber 106; a gas flow control instruction set to operate the flow control valves 178 to set a flow of sputtering gas to the chamber 106; a gas pressure control instruction set to operate the exhaust throttle valve 188 to maintain a pressure in the chamber 106; a gas energizer control instruction set to operate the gas energizer 116 to set a gas energizing power level; a temperature control instruction set to control a temperature control system 119 to control temperatures in the chamber 106; and a process monitoring instruction set to monitor the process in the chamber 106.

The present invention has been described with reference to certain preferred versions thereof; however, other versions are possible. For example, the ring assembly 20 or 20a can comprise other versions of the deposition rings 26 or 80, and features of each of these versions can be used independently or in combination with one another, as would be apparent to one of ordinary skill. The ring assemblies 20, 20a can also be used in other process chambers such as etching, CVD or cleaning chambers. Therefore, the spirit and scope of the appended claims should not be limited to the description of the preferred versions contained herein.

What is claimed is:

1. A ring assembly for a substrate support used in a substrate processing chamber, the substrate support comprising an annular ledge and an inner perimeter sidewall, and the ring assembly comprising:
(a) an L-shaped isolator ring comprising a horizontal leg resting on the annular ledge of the support, and a vertical leg abutting the inner perimeter sidewall of the support; and
(b) a deposition ring comprising an annular band having an overlap ledge that overlaps a portion of the horizontal leg of the isolator ring.

2. A ring assembly according to claim 1 wherein the horizontal leg of the isolator ring has a length that is sized smaller than the length of the annular ledge of the support.

3. A ring assembly according to claim 2 wherein the length of the horizontal leg is sized to be less than about 80% of the length of the annular ledge of the support.

4. A ring assembly according to claim 1 wherein the vertical leg of the isolator ring has a height that is sized smaller than the height of the inner perimeter sidewall of the support.

5. A ring assembly according to claim 4 wherein the vertical leg has a height of less than about 90% of the height of the inner perimeter sidewall.

6. A ring assembly according to claim 1 wherein the isolator ring is composed of a dielectric material.

7. A ring assembly according to claim 6 wherein the isolator ring comprises a ceramic.

8. A ring assembly according to claim 1 wherein the isolator ring comprises a laser textured surface.

9. A ring assembly according to claim 8 wherein the laser textured surface comprises spaced apart recesses.

10. A ring assembly according to claim 8 wherein the spaced apart recesses comprise an opening with a diameter of from about 25 to about 800 microns, a depth of from about 25 to about 800 microns, and a spacing between center-points of adjacent recesses of from about 25 to about 1000 microns.

11. A ring assembly according to claim 1 wherein the annular band has an upper wedge, which extends vertically upward and connects to an inner perimeter of the deposition ring to define a sloped surface.

12. A ring assembly according to claim 11 wherein the sloped surface comprises at least one of:
(1) an angle of at least about 5°; or
(2) an angle of up to about 25°.

13. A ring assembly according to claim 11 wherein the sloped surface comprises a textured coating.

14. A ring assembly according to claim 1 wherein the deposition ring is composed of aluminum, stainless steel or titanium.

15. A process kit for a substrate-processing chamber, the process kit comprising the ring assembly of claim 1, a cover ring to at least partially cover the deposition ring, bracket, and a fastener to attach the bracket to the deposition ring to hold the deposition ring to the annular ledge of the support.

16. A substrate-processing chamber comprising the ring assembly of claim 1, and further comprising a substrate support, gas delivery system, gas energizer and gas exhaust.

17. A ring assembly for a substrate support used in a substrate processing chamber, the substrate support comprising an annular ledge and an inner perimeter sidewall, and the ring assembly comprising:
(a) a dielectric deposition ring comprising an annular band that surrounds and overlaps the annular ledge of the support, the annular band having an inner perimeter that abuts the inner perimeter sidewall of the support, an outer perimeter, a footing that rests on the annular ledge of the support, and a first aperture therethrough;
(b) a bracket with a second aperture, the bracket having a raised lip that contacts the annular ledge of the support; and
(c) a fastener sized to pass through the first aperture of the annular band and the second aperture of the bracket to secure the deposition ring to the annular ledge of the substrate support.

18. A ring assembly according to claim 17 wherein the deposition ring comprises a ceramic.

19. A ring assembly according to claim 17 wherein the deposition ring comprises an outer rim extending upward from the outer perimeter from the annular band.

20. A ring assembly according to claim 17 wherein the deposition ring comprises an inner rim extending upward from the inner perimeter of the annular band.

21. A ring assembly according to claim 20 wherein the outer and inner rims are connected by a concave surface that is curved at a radius of at least about 50°.

22. A ring assembly according to claim 21 wherein the concave surface is curved at a radius of from about 30° to about 80°.

23. A ring assembly according to claim 21 wherein the concave surface is substantially absent bumps.

24. A ring assembly according to claim 17 wherein the fastener comprises a swiveling fastener that is capable of rotating the bracket to brace the bracket against the support.

25. A process kit for a substrate-processing chamber, the process kit comprising the ring assembly of claim 17, and a cover ring to at least partially cover the deposition ring.

26. A substrate-processing chamber comprising the ring assembly of claim 17, and further comprising a substrate support, gas delivery system, gas energizer and gas exhaust.
